(19) United States
(12) Patent Application Publication
(10) Pub. No.: US 2026/0029679 A1
(43) Pub. Date: Jan. 29, 2026

(54) DISPLAY SUBSTRATE, DISPLAY PANEL AND DISPLAY APPARATUS

(71) Applicants: Hefei Xinsheng Optoelectronics Technology Co., Ltd., Hefei, Anhui (CN); BOE Technology Group Co., Ltd., Beijing (CN)

(72) Inventors: Ruifang DU, Beijing (CN); Meng GENG, Beijing (CN); Guangying MOU, Beijing (CN); Ran ZHANG, Beijing (CN); Yongcan WANG, Beijing (CN); Xiaoye MA, Beijing (CN)

(21) Appl. No.: 18/993,560

(22) PCT Filed: Apr. 16, 2024
(86) PCT No.: PCT/CN2024/088060

§ 371 Date: Jan. 12, 2025

(30) Foreign Application Priority Data
May 30, 2023 (CN) 202310629140.4

(51) Int. Cl. G02F 1/1362; G02F 1/1368

(52) U.S. Cl. CPC G02F 1/136286; G02F 1/136204; G02F 1/136254; G02F 1/1368

(57) ABSTRACT

A display substrate is provided to include a base substrate including an active display region and a dummy region, the dummy region includes at least one first dummy sub-region arranged in a first direction together with the active display region; active gate lines in the active display region and extending along the first direction, at least one end of at least one active gate line extends into a first dummy sub-region on the same side as the at least one end; and at least one dummy data line within the first dummy sub-region and extending along a second direction; an orthographic projection of an end of the at least one active gate line in the first dummy sub-region on the base substrate does not overlap with an orthographic projection of any dummy data line on the base substrate. A display panel and a display apparatus are further provided.

### TECHNICAL FIELD

The present disclosure relates to the field of display technology, and in particular to a display substrate, a display panel and a display apparatus.

### BACKGROUND

A basic structure of a thin film transistor-liquid crystal display (TFT-LCD) generally includes an array substrate, an opposite substrate, and a liquid crystal (LC) layer disposed between the array substrate and the opposite substrate, and the array substrate is provided with various driving circuits and signal lines for displaying. A structural design for the array substrate directly affects the performance of the product.

### SUMMARY

In a first aspect, an embodiment of the present disclosure provides a display substrate, including: a base substrate including an active display region and a dummy region surrounding the active display region, the dummy region includes at least one first dummy sub-region arranged in a first direction together with the active display region; a plurality of active gate lines in the active display region and extending along the first direction, at least one end of at least one active gate line each extends into a first dummy sub-region of the at least one first dummy sub-region on the same side as the end; and at least one dummy data line within the at least one first dummy sub-region and extending along a second direction, the first direction intersects with the second direction; an orthographic projection of an end of the at least one active gate line in the first dummy sub-region on the base substrate does not overlap with an orthographic projection of any dummy data line on the base substrate.

In some embodiments, the dummy region includes two first dummy sub-regions on two opposite sides of the active display region in the first direction, respectively; and two ends of each of the at least one active gate line extend into the two first dummy sub-regions at the two opposite sides corresponding to the two ends, respectively.

In some embodiments, the end of each of the at least one active gate line extending to the corresponding first dummy sub-region is on a side of one dummy data line, farthest from the active display region in the first dummy sub-region where the end is located, away from the active display region.

In some embodiments, the at least one dummy data line within the first dummy sub-region includes two or more dummy data lines; and the end of each of the at least one active gate line extending to the corresponding first dummy sub-region is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region.

In some embodiments, the dummy region includes two first dummy sub-regions on two opposite sides of the active display region in the first direction, respectively, the base substrate further includes a peripheral region surrounding the dummy region and including: two first peripheral sub-regions, each of which is on a side of a corresponding one of the two first dummy sub-regions away from the active display region, and the display substrate further includes a first gate driving circuit and a second gate driving circuit in the two first peripheral sub-regions, respectively; the plurality of active gate lines in the active display region include: a plurality of first gate lines and a plurality of second gate lines alternately arranged along the second direction; an end of each first gate line close to the first gate driving circuit is on a side of one dummy data line, farthest from the active display region in the first dummy sub-region where the end is located, away from the active display region, and the first gate line is connected to a corresponding driving signal output terminal in the first gate driving circuit; and an end of each second gate line close to the second gate driving circuit is on a side of one dummy data line, farthest from the active display region in the first dummy sub-region where the end is located, away from the active display region, and the second gate line is connected to a corresponding driving signal output terminal in the second gate driving circuit.

In some embodiments, the at least one dummy data line within the first dummy sub-region includes two or more dummy data lines; an end of each first gate line close to the first gate driving circuit is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region; and an end of each second gate line close to the second gate driving circuit is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region.

In some embodiments, the dummy region includes two first dummy sub-regions on two opposite sides of the active display region in the first direction, respectively, the base substrate further includes a peripheral region surrounding the dummy region and including: two first peripheral sub-regions, each of which is on a side of a corresponding one of the two first dummy sub-regions away from the active display region, and the display substrate further includes a first gate driving circuit and a second gate driving circuit in the two first peripheral sub-regions, respectively; an end of each active gate line close to the first gate driving circuit is on a side of one dummy data line, farthest from the active display region in the first dummy sub-region where the end is located, away from the active display region, and the active gate line is connected to a corresponding driving signal output terminal in the first gate driving circuit; and an end of each active gate line close to the second gate driving circuit is on a side of one dummy data line, farthest from the active display region in the first dummy sub-region where the end is located, away from the active display region, and the active gate line is connected to a corresponding driving signal output terminal in the second gate driving circuit.

In some embodiments, the display substrate further includes: a common voltage line in the dummy region; and the plurality of active gate lines and the common voltage line are arranged in a same layer.

In some embodiments, a distance in the first direction between the end of each active gate line extending to the corresponding first dummy sub-region and any one dummy data line in the first dummy sub-region where the end is located is greater than or equal to 7 μm and less than or equal to 20 μm.

In some embodiments, the display substrate further includes: a common voltage line in the dummy region; and a plurality of active data lines in the active display region, extending along the second direction, and insulated from the common voltage line; and the at least one dummy data line within the first dummy sub-region includes two or more dummy data lines connected to the common voltage line, and at least two dummy data lines are not in contact with each other.

In some embodiments, the display substrate further includes: first conductive connection structures on a side of the two or more dummy data lines away from the base substrate; the two or more dummy data lines are connected to the common voltage line through the first conductive connection structures, respectively, the first conductive connection structures each include a first portion and a second portion connected to each other, the first portion is connected to the corresponding dummy data line, and the second portion is connected to the common voltage line.

In some embodiments, the dummy region further includes: two second dummy sub-regions on two opposite sides of the active display region in the second direction; the common voltage line includes: two second common voltage sub-lines in the two second dummy sub-regions, respectively, and extending along the first direction; and two ends of each dummy data line are connected to the two second common voltage sub-lines through the corresponding first conductive connection structures, respectively.

In some embodiments, orthographic projections of the two ends of each dummy data line on the base substrate overlap with orthographic projections of the two second common voltage sub-lines on the base substrate, respectively.

In some embodiments, the two ends of each dummy data line are a first end and a second end, respectively; first ends of at least two dummy data lines in the same first dummy sub-region are connected to different portions of the same first conductive connection structure; and second ends of the at least two dummy data lines in the same first dummy sub-region are connected to different portions on the same first conductive connection structure.

In some embodiments, the display substrate further includes: a gate insulating layer on a side of the common voltage line away from the base substrate, the at least one dummy data line is on a side of the gate insulating layer away from the base substrate; a planarization layer on a side of the at least one dummy data line away from the base substrate; a pixel electrode layer on a side of the planarization layer away from the base substrate, and including a plurality of pixel electrodes; and a passivation layer on a side of the pixel electrode layer away from the base substrate; the first conductive connection structures are on a side of the passivation layer away from the base substrate, the first portion is connected to the corresponding dummy data line through a via in the passivation layer exposing a surface of the corresponding dummy data line, and the second portion is connected to the common voltage line through a via in the passivation layer, the planarization layer, and the gate insulating layer exposing a surface of the common voltage line.

In some embodiments, the display substrate further includes: a common electrode on a side of the plurality of active data lines away from the base substrate; and a portion of the common electrode serves as the first conductive connection structure.

In some embodiments, the base substrate further includes a peripheral region surrounding the dummy region, and including: a first peripheral sub-region on a side of the first dummy sub-region away from the active display region, a gate driving circuit is arranged in the first peripheral sub-region, and at least one end of each active gate line is connected to a corresponding driving signal output terminal in the gate driving circuit through a corresponding second conductive connection structure; the common voltage line includes: a first common voltage sub-line in the first dummy sub-region, extending along the second direction and between the plurality of active gate lines and the gate driving circuit; and a portion of the first common voltage sub-line directly opposite to the end of each active gate line in the first direction is an avoiding portion, and an orthographic projection of each second conductive connection structure on the base substrate does not overlap with an orthographic projection of the corresponding avoiding portion on the base substrate.

In some embodiments, the common voltage line is in the same layer as the plurality of active gate lines; and the second conductive connection structure is in the same layer as the plurality of active data lines and the at least one dummy data line.

In some embodiments, the base substrate further includes a peripheral region surrounding the dummy region, and including: a bonding sub-region, first peripheral sub-regions and first corner sub-regions, the bonding sub-region is on one side of the active display region in the second direction, each first peripheral sub-region is on a side of the corresponding first dummy sub-region away from the active display region, and each first corner sub-region is between the bonding sub-region and the corresponding first peripheral sub-region; the display substrate further includes a plurality of test terminals in each first corner sub-region and a plurality of test lines in each first peripheral sub-region, and one end of each test line close to the bonding sub-region extends into the first corner sub-region and is connected to the corresponding test terminal; the display substrate further includes a plurality of first electrostatic discharge units in each first corner sub-region, and a portion of each test line in the first corner sub-region is connected to the corresponding first electrostatic discharge unit through a corresponding third conductive connection structure, and each test terminal and the test line connected to the test terminal share the same first electrostatic discharge unit.

In some embodiments, each first electrostatic discharge unit includes: a first transistor and a second transistor; a gate electrode of the first transistor and a first electrode of the first transistor are connected to the corresponding third conductive connection structure, and a second electrode of the first transistor is connected to the common voltage line; and a gate electrode of the second transistor and a second electrode of the second transistor are connected to the common voltage line, and a first electrode of the second transistor is connected to the corresponding third conductive connection structure.

In some embodiments, the peripheral region further includes: a bonding opposite sub-region and second corner sub-regions, the bonding opposite sub-region and the bonding sub-region are on two opposite sides of the active display region in the second direction, respectively, and each second corner sub-region is between the bonding opposite sub-region and the corresponding first peripheral sub-region; the display substrate further includes a plurality of second electrostatic discharge units in each second corner sub-region, one end of each test line close to the bonding opposite sub-region extends into the corresponding second corner sub-region, and a portion of each test line in the second corner sub-region is connected to the corresponding second electrostatic discharge unit through a corresponding fourth conductive connection structure; and each test terminal and the test line connected to the test terminal share the same second electrostatic discharge unit.

In some embodiments, each second electrostatic discharge unit includes: a third transistor and a fourth transistor; a gate electrode of the third transistor and a first electrode of the third transistor are connected to the corresponding fourth conductive connection structure, and a second electrode of the third transistor is connected to the common voltage line; and a gate electrode of the fourth transistor and a second electrode of the fourth transistor are connected to the common voltage line, and a first electrode of the fourth transistor is connected to the corresponding fourth conductive connection structure.

In some embodiments, the plurality of test lines are in the same layer as the common voltage line; and the third conductive connection structure, the fourth conductive connection structure and the at least one dummy data line are in the same layer.

In a second aspect, an embodiment of the present disclosure provides a display panel, including: the display substrate in the above first aspect and an opposite substrate opposite to the display substrate.

In a third aspect, an embodiment of the present disclosure provides a display apparatus, including: the display panel in the above second aspect and a source driving chip; the source driving chip is connected to the plurality of active data lines and configured to provide a data voltage for the plurality of active data lines.

### BRIEF DESCRIPTION OF DRAWINGS

FIG. 1 is a schematic top view of a display substrate according to an embodiment of the present disclosure;

FIG. 2A and FIG. 2B are two schematic top views each showing one end of an active gate line in a first dummy sub-region on the same side as the end of the active gate line according to an embodiment of the present disclosure;

FIG. 3A is another schematic top view of a display substrate according to an embodiment of the present disclosure;

FIG. 3B is another schematic top view of a display substrate according to an embodiment of the present disclosure;

FIGS. 4A to 4D are micrographs of a region A, a region B, a region C, and a region D of FIG. 1, respectively;

FIG. 5 is a schematic cross-sectional view taken along a line P-P′ of FIG. 4A;

FIG. 6 is a schematic diagram of a circuit structure of an active pixel unit in an active display region according to an embodiment of the present disclosure;

FIG. 7 is a schematic top view showing a plurality of dummy data lines being connected to a common voltage line in a same first dummy sub-region in a related art;

FIG. 8 is another schematic top view of a display substrate according to an embodiment of the present disclosure;

FIG. 9 is a schematic top view of a structure at a test terminal in a related art;

FIG. 10 is a schematic top view of a structure at a test terminal according to an embodiment of the present disclosure;

FIG. 11 is a schematic diagram of a circuit structure of a first electrostatic discharge unit according to an embodiment of the present disclosure; and

FIG. 12 is a schematic diagram of a circuit structure of a second electrostatic discharge unit according to an embodiment of the present disclosure.

### DETAIL DESCRIPTION OF EMBODIMENTS

In order to enable one of ordinary skill in the art to better understand the technical solutions of the present disclosure, a display substrate, a display panel and a display apparatus provided by the present disclosure will be described in further detail with reference to the accompanying drawings.

Numerous specific details of the present disclosure, such as structures, materials, dimensions, treatment processes and processing techniques of the components, are described below to provide a more thorough understanding of the present disclosure. However, as will be understood by one of ordinary skill in the art, the present disclosure may be practiced without these specific details.

The terms “first”, “second”, and the like used in the embodiments of the present disclosure are not intended to indicate any order, quantity, or importance, but rather are used for distinguishing one element from another. Similarly, the term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections.

The description used in the embodiments of the present disclosure that a structure A surrounds a structure B, means that the structure A is located outside the structure B and surrounds at least a portion of the structure B. For example, the structure A surrounds the structure B on a side, two sides, or more sides, which is not limited to the structure A necessarily surrounding the entire periphery of the structure B (at an angle of 360°).

The term “about”, “around” or “approximately” as used in the embodiments of the present disclosure includes a stated value, and means that the stated value is within an acceptable range of deviation for a particular value as determined by one of ordinary skill in the art in view of a measurement in question and an error associated with a measurement of a particular quantity (i.e., a limitation of a measurement system). For example, the term “about” may mean that a difference from the stated value is within one or more standard deviations, or within ±30%, ±20%, ±10%, or ±5%.

In addition, for an expression of a range from M to N in the embodiments of the present disclosure, the defined range includes two endpoints of M and N.

A transistor used in the embodiments of the present disclosure may be a thin film transistor, a field effect transistor or any other device having the same characteristics. In this embodiment, coupling modes of a drain electrode and a source electrode of each transistor may be coupled to each other in an interchangeable manner. Therefore, there is actually no difference between the drain electrode and the source electrode of each transistor in the embodiments of the present disclosure. Herein, only in order to distinguish two electrodes of the transistor except for a control electrode (i.e., a gate electrode) from each other, one of the electrodes is referred to as a drain electrode and the other electrode is referred to as a source electrode. In the following description, one of a source electrode and a drain electrode of each transistor is referred to as a first electrode, and the other electrode is referred to as a second electrode.

In the embodiments of the present disclosure, two structures arranged in a same layer means that the two structures are formed by performing a patterning process on a same material layer. That is, the two structures may be simultaneously formed by patterning the same material layer, and the two structures arranged in the same layer may be directly connected to each other or disconnected from each other. The patterning process performed on the material layer in the present disclosure generally includes coating photoresist, exposing, developing, etching, stripping photoresist, and the like. If a material layer to be patterned is made of a photoresist material, the patterning of the material layer may be implemented by exposing and developing.

The research shows that each active gate line in an active display region of a display substrate has a linear structure, and static electricity is usually accumulated at an end of the linear structure. That is, a position where accumulated static electricity is generally discharged is at the end of the active gate line. The static electricity is accumulated at the end of the active gate line and discharged, which easily damages the structure near the end. Especially, when the end of the active gate line overlaps with a dummy data line in a dummy region of the display substrate in a direction perpendicular to a base substrate, once a gate insulating layer is broken down due to the discharge of the static electricity accumulating at the end of the active gate line, the active gate line is short-circuited to the dummy data line. Furthermore, the dummy data line is electrically connected to a common voltage line, so that a common voltage may be applied to the active gate line short-circuited to the dummy data line, and thus an active pixel unit connected to the active gate line may have poor display quality. In order to effectively solve the technical problem, the present disclosure provides a new display substrate.

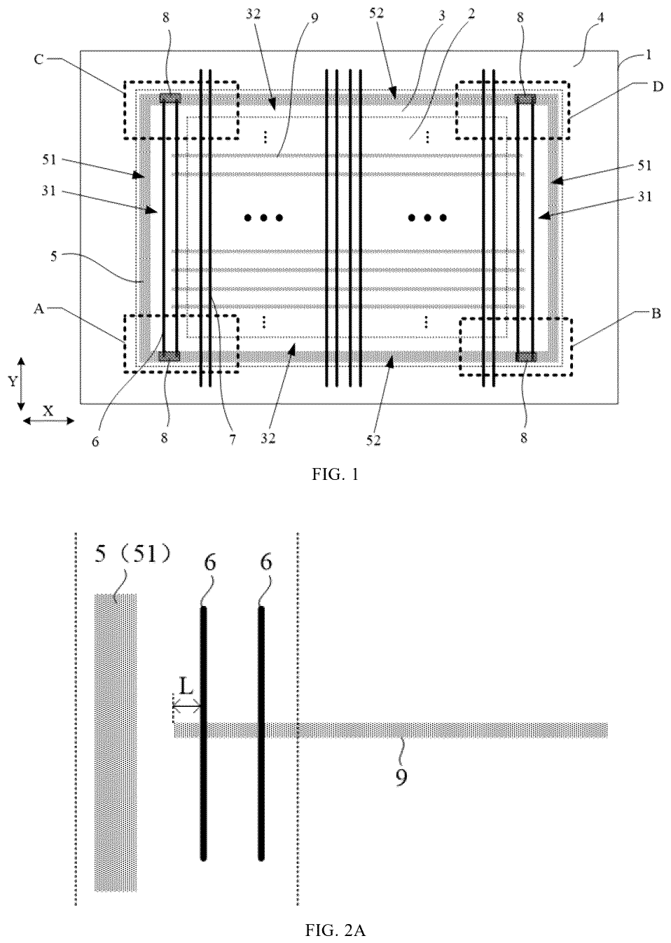

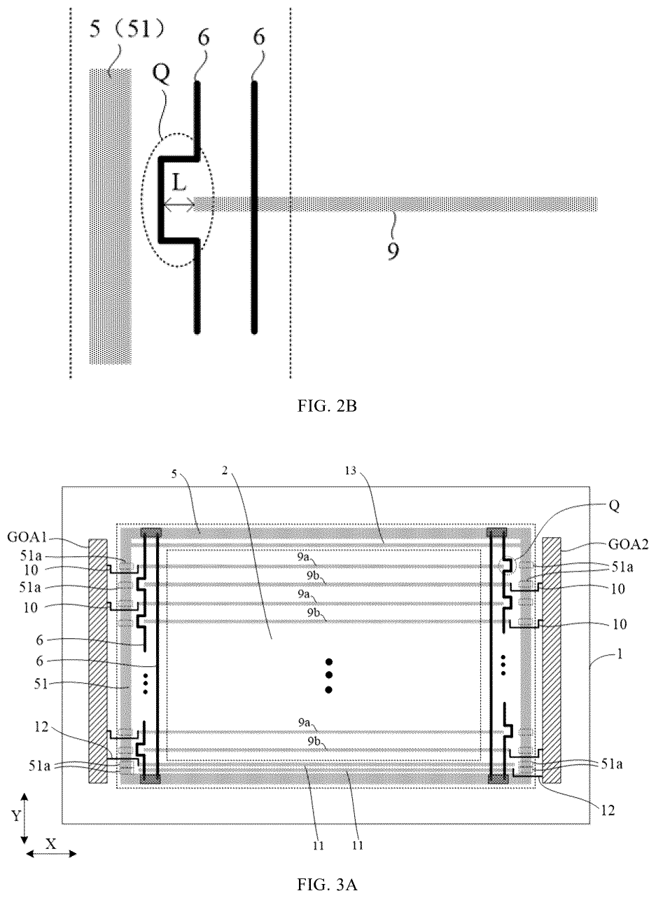

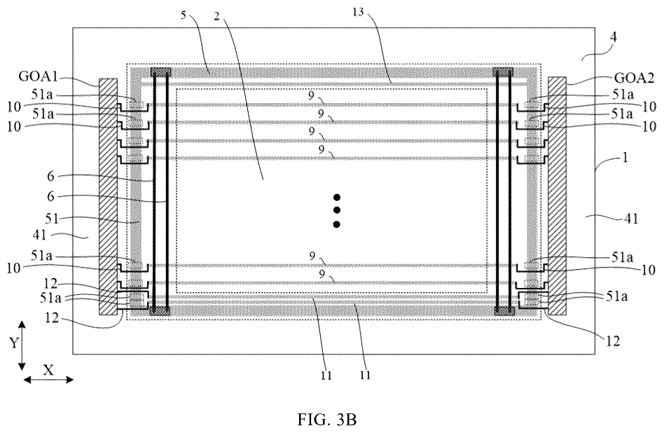

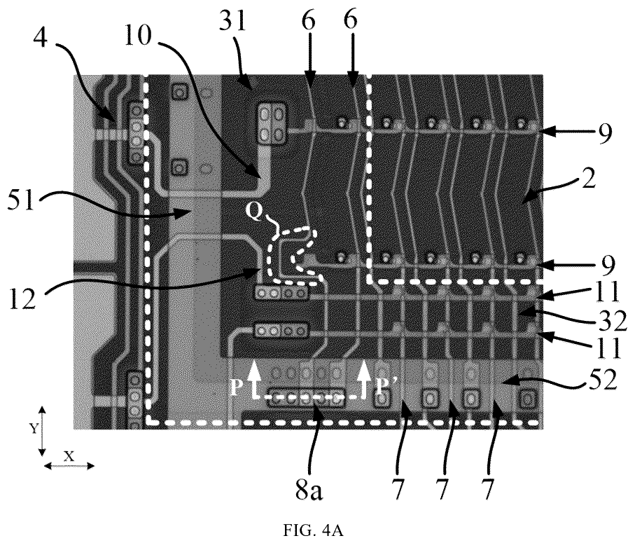

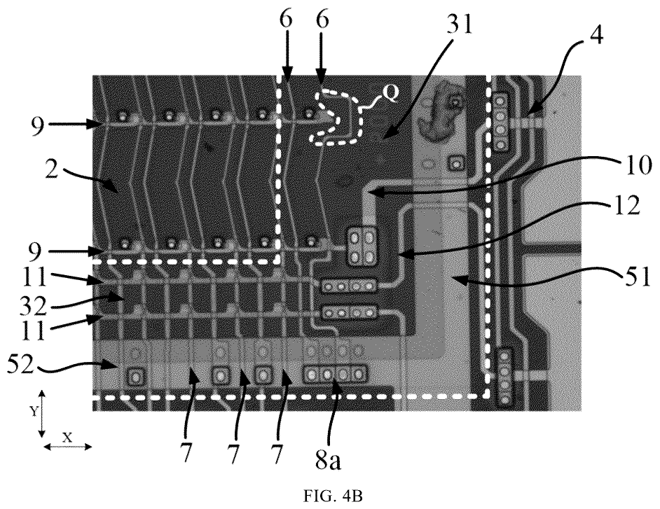

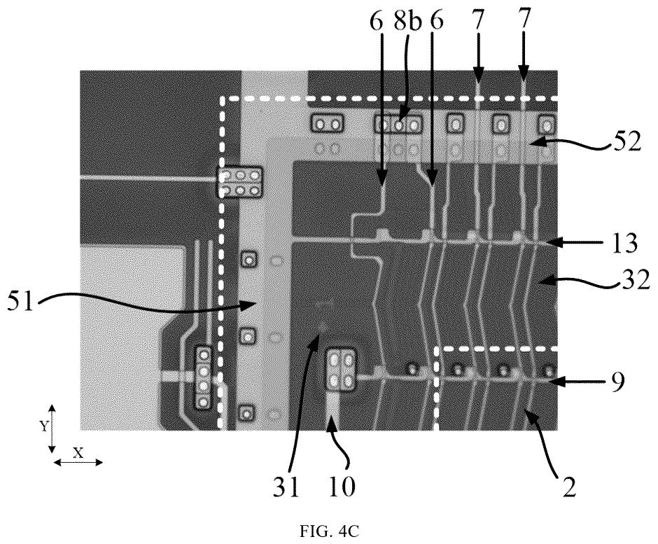

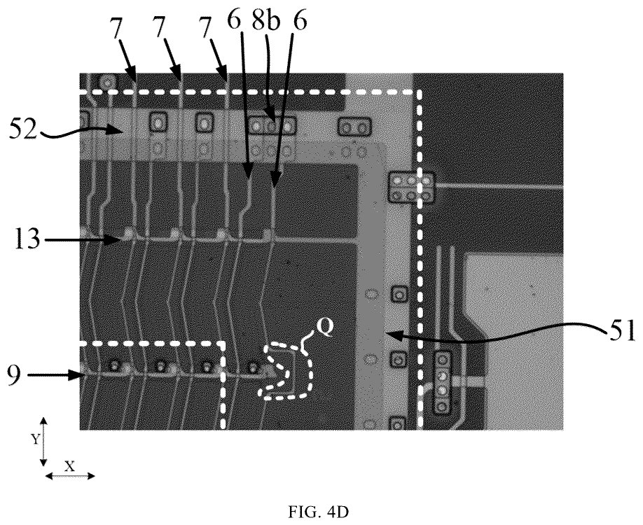

FIG. 1 is a schematic top view of a display substrate according to an embodiment of the present disclosure; FIG. 2A and FIG. 2B are two schematic top views showing one end of an active gate line in a first dummy sub-region on the same side as the end of the active gate line, respectively, according to an embodiment of the present disclosure; FIG. 3A is another schematic top view of a display substrate according to an embodiment of the present disclosure; FIG. 3B is another schematic top view of a display substrate according to an embodiment of the present disclosure; FIGS. 4A to 4D are micrographs of a region A, a region B, a region C, and a region D of FIG. 1, respectively; FIG. 5 is a schematic cross-sectional view taken along a line P-P′ of FIG. 4A; FIG. 6 is a schematic diagram of a circuit structure of an active pixel unit in an active display region according to an embodiment of the present disclosure; FIG. 7 is a schematic top view showing a plurality of dummy data lines being connected to a common voltage line in a same first dummy sub-region in a related art. As shown in FIGS. 1 to 7, the display substrate includes: a base substrate 1, a plurality of active gate lines 9 and at least one dummy data line 6.

The base substrate 1 includes: an active display region (AA, also referred to as an active area) 2 and a dummy region surrounding the active display region 2, and the dummy region 3 includes: at least one first dummy sub-region 31 arranged in a first direction X together with the active display region 2. The active gate lines 9 are located in the active display region 2 and extend along the first direction, and at least one end of at least one active gate line 9 extends into a first dummy sub-region 31 on the same side as the at least one end. The at least one dummy data line 6 is located within the first dummy sub-region 31 and extends along a second direction, and the first direction intersects with the second direction. An orthographic projection of an end of at least one active gate line 9 in the first dummy sub-region on the base substrate 1 does not overlap with an orthographic projection of any dummy data line 6 on the base substrate 1.

In the present disclosure, the position relationship between the at least one active gate line 9 and the at least one dummy data line 6 is designed as described above, and the orthographic projection of the end of at least one active gate line 9 located in the first dummy sub-region on the base substrate 1 does not overlap with the orthographic projection of any dummy data line 6 on the base substrate 1, so that even if the gate insulating layer is broken down due to the discharge of the static electricity accumulating at the end of the active gate line 9 in the first dummy sub-region 31, the problem of the active gate line 9 short-circuited to the dummy data line 6 can be effectively reduced, or even completely avoided since the end and the dummy data line 6 are arranged in a staggered manner.

In some embodiments, the display substrate further includes a common voltage line 5 disposed in the dummy region 3 of the display substrate, and active data lines 7 disposed in the active display region 2 of the display substrate. The active data lines 7 extend along the second direction Y, and are insulated from the common voltage line 5.

In the display substrate, in view of a manufacturing process or other factor, the dummy region may be disposed at the periphery of the active display region, and dummy structures, such as at least one dummy data line 6, may be disposed in the dummy region. Unlike the data voltage for display applied to the active data lines 7 in the active display region, a common voltage is applied to the dummy data line 6 in the dummy region. Specifically, the active data lines 7 extend to a peripheral region 4 (specifically, a bonding sub-region 42, which will be described in detail below) outside the dummy region 3, and therefore, are electrically connected to a source driving chip subsequently bound to the bonding sub-region 42, and receive the data voltage for display output by the source driving chip. The dummy data line 6 extends to be connected to the common voltage line 5 and receives the common voltage provided from the common voltage line 5.

In some embodiments, the dummy region 3 includes two first dummy sub-regions 31 located on two opposite sides of the active display region 2 in the first direction X. Each of two ends of each active gate line 9 extends into the first dummy sub-region 31 on the same side as the end.

Referring to FIGS. 2A and 2B, in the case of FIG. 2A, the end of each active gate line 9 extending to the corresponding first dummy sub-region 31 is located on a side of one dummy data line 6, farthest from the active display region 2 located in the first dummy sub-region 31 where the end is located, away from the active display region 2. In the case shown in FIG. 2B, the end of each active gate line 9 extending to the corresponding first dummy sub-region 31 is located between two dummy data lines 6 farthest from the active display region 2 located in the first dummy sub-region 31 where the end is located, and a portion Q, opposite to the end in the first direction X, of the one dummy data line farthest from the active display region 2 located in the first dummy sub-region 31 where the end is located, protrudes away from the active display region 2, so that the dummy data line bypasses the end. With such the design, on one hand, the end of the active gate line 9 and the dummy data line 6 are arranged in a staggered manner. On the other hand, the end of the active gate line 9 may be as close as possible to a position of the gate driving circuit (which will be described in detail below), so that the active gate line 9 is easily connected to a corresponding driving signal output terminal in the gate driving circuit.

Of course, the two cases of FIG. 2A and FIG. 2B are only two different examples in the embodiments of the present disclosure, and do not limit the technical solution of the present disclosure.

In some embodiments, a distance (for example, a distance L in FIGS. 2A and 2B) in the first direction X between the end of each active gate line 9 extending to the corresponding first dummy sub-region 31 and any one dummy data line 6 in the first dummy sub-region 31 where the end is located is greater than or equal to 7 μm and less than or equal to 20 μm. For example, the distance is 7 μm, 10 μm, 13 μm, 16 μm, or 20 μm or the like.

It should be noted that in the present disclosure, the distance in the first direction between the “end” and the dummy data line 6 means: a minimum distance between an orthographic projection of an edge of the end on the base substrate 1 and an orthographic projection of the dummy data line 6 on the base substrate 1.

Referring to FIGS. 3A, 4A to 4D, in some embodiments, the dummy region 3 includes two first dummy sub-regions 31 located at two opposite sides of the active display region 2 in the first direction X, respectively, and the base substrate 1 further includes the peripheral region 4 surrounding the dummy region 3, and including: two first peripheral sub-regions 41, each of which is located on a side of a corresponding one of the two first dummy sub-regions 31 away from the active display region 2. The two first peripheral sub-regions 41 are respectively provided with a first gate driving circuit GOA1 and a second gate driving circuit GOA2. The plurality of active gate lines 9 located in the active display region 2 include: a plurality of first gate lines 9a and a plurality of second gate lines 9b alternately arranged along the second direction Y. An end of each first gate line 9a close to the first gate driving circuit GOA1 is located on a side of one dummy data line 6, farthest from the active display region 2 located in the first dummy sub-region 31 where the end is located, away from the active display region 2, and the first gate line 9a is connected to a corresponding driving signal output terminal in the first gate driving circuit GOA1. An end of each second gate line 9b close to the second gate driving circuit GOA2 is located on a side of one dummy data line 6, farthest from the active display region 2 located in the first dummy sub-region 31 where the end is located, away from the active display region 2, and the second gate line 9b is connected to a corresponding driving signal output terminal in the second gate driving circuit GOA2.

In some embodiments, an end of each first gate line 9a close to the second gate driving circuit GOA2 is located between two dummy data lines 6 farthest from the active display region 2 located in the first dummy sub-region 31 where the end is located, and a portion Q, opposite to the end in the first direction X, of the one dummy data line farthest from the active display region 2 located in the first dummy sub-region 31 where the end is located, protrudes away from the active display region 2.

An end of each second gate line 9b close to the first gate driving circuit GOA1 is located between two dummy data lines 6 farthest from the active display region 2 located in the first dummy sub-region 31 where the end is located, and a portion Q, opposite to the end in the first direction X, of the one dummy data line farthest from the active display region 2 located in the first dummy sub-region 31 where the end is located, protrudes away from the active display region 2.

In the embodiment of the present disclosure, the first gate lines 9a may be odd-numbered active gate lines 9 in the active display region 2, and the second gate lines 9b may be even-numbered active gate lines 9 in the active display region 2. Alternatively, the first gate lines 9a may be even-numbered active gate lines 9 in the active display region 2, and the second gate lines 9b may be odd-numbered active gate lines 9 in the active display region 2. In the case of FIG. 3A, the first gate lines 9a are connected to the first gate driving circuit GOA1, the second gate line 9b is connected to the second gate driving circuit GOA2, and the first gate driving circuit GOA1 and the second gate driving circuit GOA2 alternately drive the active gate lines 9.

Referring to FIGS. 4A to 4D, for example, a first dummy gate line 13 (as an example, one first dummy gate line is shown in the drawings) and a second dummy gate line 11 (as an example, two second dummy gate lines shown in the drawings) are disposed in two second dummy sub-regions 32, respectively. As an example, the first dummy gate line 13 (the specific number may be designed as required) is disposed in the second dummy sub-region 32 on a side of the first active gate line 9 away from the second active gate line 9, and the second dummy gate line 11 (the specific number may be designed as required) is disposed in the second dummy sub-region 32 on a side of the last active gate line 9 away from the last but one active gate line 9 (the specific number may be designed as required). The first dummy gate line 13 may extend into the first dummy sub-region 31 to be connected to the common voltage line 5, and may be applied with the common voltage. The second dummy gate line 11 may be connected to the corresponding first gate driving circuit GOA1 and/or the second gate driving circuit GOA2 through a corresponding conductive connection structure 12 to receive a gate driving signal provided by the first gate driving circuit GOA1 and/or the second gate driving circuit GOA2.

Referring to FIG. 3B, unlike the case shown in FIG. 3A in which the first gate driving circuit GOA1 and the second gate driving circuit GOA2 alternately drive the active gate lines 9, in the case shown in FIG. 3B, each active gate line 9 may be driven by the first gate driving circuit GOA1 and the second gate driving circuit GOA2 at the same time, that is, the active gate lines 9 may be driven on both sides. With such the design, the speed of loading the gate driving signals on the active gate lines can be increased.

Specifically, the dummy region 3 includes two first dummy sub-regions 31 respectively located on two opposite sides of the active display region 2 in the first direction X, and the base substrate 1 further includes the peripheral region 4 surrounding the dummy region 3, and including: the two first peripheral sub-regions 41, each of which is located on a side of a corresponding one of the two first dummy sub-regions 31 away from the active display region 2. The first gate driving circuit GOA1 and the second gate driving circuit GOA2 are provided in the two first peripheral sub-regions 41, respectively.

An end of each active gate line 9 close to the first gate driving circuit GOA1 is located on a side of one dummy data line 6, farthest from the active display region 2 located in the first dummy sub-region 31 where the end is located, away from the active display region 2, and the active gate line 9 is connected to a corresponding driving signal output terminal in the first gate driving circuit GOA1. An end of each active gate line 9 close to the second gate driving circuit GOA2 is located on a side of one dummy data line 6, farthest from the active display region 2 located in the first dummy sub-region 31 where the end is located, away from the active display region 2, and the active gate line 9 is connected to a corresponding driving signal output terminal in the second gate driving circuit GOA2.

With continued reference to FIGS. 3A and 3B, in some embodiments, the ends of the active gate lines 9 may be connected to corresponding signal output terminals in corresponding gate driving circuits through corresponding second conductive connection structures 10, and the second conductive connection structures 10 will be described in detail below.

Referring to FIG. 7, in the related art, the same-side ends (that is, the ends on the same side) of a plurality of dummy data lines 06 in the same dummy sub-region are connected together in the first dummy sub-region 031 to form a common end DP, which is in turn connected to the common voltage line 05 through a conductive connection structure 801, so that each dummy data line 06 is electrically connected to the common voltage line 05. However, it is found in practical applications that each dummy data line 06 substantially has a linear structure, and static electricity is generally accumulated at an end of the linear structure. The same-side ends of the dummy data lines 06 are directly connected together to form the common end DP, so that the static electricity accumulated at the common end DP is increased, and thus the discharge of the accumulated static electricity is likely to occur, and the discharge of the accumulated static electricity at the common end DP easily causes some damage to a peripheral structure (such as the common voltage line and an insulating layer).

Referring to FIG. 1 and FIG. 3A to FIG. 4D, in order to effectively solve the above technical problem, in the embodiment of the present disclosure, at least two dummy data lines 6 are not in contact with each other while the dummy data lines 6 extend to be connected to the common voltage line 5, so as to prevent the static electricity on two or even more dummy data lines 6 from being accumulated together, thereby effectively reducing the risk of the discharge of the accumulated static electricity on the dummy data lines 6.

It should be noted that FIG. 1 exemplarily shows that the dummy region 3 includes the two first dummy sub-regions 31 located at two opposite sides of the active display region 2 in the first direction X, respectively, and each first dummy sub-region 31 is provided with the two dummy data lines 6. In the present disclosure, the dummy region 3 may alternatively include only one first dummy region 3 located on one side of the active display region 2 in the first direction X, which also belongs to the protection scope of the present disclosure.

In the embodiment of the present disclosure, the plurality of active gate lines 9 are disposed in the active display region 2, and extend along the first direction X, and the active gate lines 9 and the active data lines 7 define a plurality of active pixel units. As shown in FIG. 6, each active pixel unit includes a thin film transistor T and a pixel electrode PIX, a control electrode of the thin film transistor T is connected to the corresponding active gate line 9, a first electrode of the thin film transistor T is connected to the corresponding active data line 7, and a second electrode of the thin film transistor T is connected to the pixel electrode PIX.

In some embodiments, the active gate lines 9 and the common voltage line 5 are disposed in the same layer. The active data lines 7 and the dummy data lines 6 are disposed in the same layer.

Referring to FIGS. 1 to 5, in some embodiments, the display substrate further includes: first conductive connection structures 8 located on a side of the dummy data lines 6 away from the base substrate 1. The dummy data lines 6 are connected to the common voltage line 5 through the first conductive connection structures 8, respectively. The first conductive connection structures 8 each include first portions 81 and second portions 82 connected to each other, the first portions 81 are connected to the corresponding dummy data lines 6, and the second portions 82 are connected to the common voltage line 5.

In some embodiments, an orthographic projection of each first conductive connecting structure 8 on the base substrate 1 is entirely located within an orthographic projection of the common voltage line 5 on the base substrate 1.

In some embodiments, referring to FIG. 1, the dummy region 3 further includes: two second dummy sub-regions 32 located on two opposite sides of the active display region 2 in the second direction Y. The common voltage line 5 includes: two second common voltage sub-lines 52 located in the two second dummy sub-regions 32, respectively, and extending along the first direction X. Two ends of each dummy data line 6 are connected to the two second common voltage sub-lines 52 through the corresponding first conductive connection structures 8, respectively.

In some embodiments, orthographic projections of the two ends of each dummy data line 6 on the base substrate 1 overlap with orthographic projections of two second common voltage sub-lines 52 on the base substrate 1, respectively. At this time, each end of the dummy data line 6 directly extends to a region where the corresponding second common voltage sub-line 52 is located, and the end of the dummy data line 6 is closer to the corresponding second common voltage sub-line 52, thereby reducing a resistance between the end of the dummy data line 6 and the corresponding second common voltage sub-line 52.

In some embodiments, the two ends of each dummy data line 6 are a first end and a second end (for example, as shown, a lower end of the dummy data line 6 is the first end, and an upper end of the dummy data line 6 is the second end). Referring to FIGS. 4A and 4B, the first ends of all the dummy data lines 6 located in the same first dummy sub-region 31 are connected to different portions of the same first conductive connection structure 8a. Referring to FIGS. 4C and 4D, the second ends of all the dummy data lines 6 located in the same first dummy sub-region 31 are connected to different portions on the same first conductive connection structure 8b.

That is, the first ends of all the dummy data lines 6 located in the same first dummy sub-region 31 correspond to the same first conductive connection structure 8a, and the second ends of all the dummy data lines 6 located in the same first dummy sub-region 31 correspond to the same first conductive connection structure 8b. With such a design, the number of the first conductive connection structures 8 required to be arranged can be effectively reduced, thereby simplifying the product structure.

In some embodiments, the display substrate further includes: a gate insulating layer GI, a planarization layer PLN, a pixel electrode layer (not shown), and a passivation layer PVX. The gate insulating layer GI is located on a side of the common voltage line 5 and the active gate lines 9 away from the base substrate 1. The dummy data lines 6 and the active data lines 7 are located on a side of the gate insulating layer GI away from the base substrate 1. The planarization layer PLN is located on a side of the dummy data lines 6 away from the base substrate 1. The pixel electrode layer is located on a side of the planarization layer PLN away from the base substrate 1, and includes a plurality of pixel electrodes PIX. The passivation layer PVX is located on a side of the pixel electrode layer away from the base substrate 1. The first conductive connection structures 8 are located on a side of the passivation layer PVX away from the base substrate 1, the first portions of the first conductive connection structures 8 are connected to (in contact with) the corresponding dummy data lines 6 through vias in the passivation layer PVX, and the second portions of the first conductive connection structures 8 are connected to (in contact with) the common voltage line 5 through vias in the passivation layer PVX, the planarization layer PLN, and the gate insulating layer GI.

In some embodiments, a common electrode COM is provided on a side of the active data lines 7 away from the base substrate 1. A part of the common electrode COM is further used as the first conductive connection structures 8. In the embodiment of the present disclosure, the part of the common electrode is used as the first conductive connection structures 8, which simplifies the product structure. Accordingly, the display substrate may be an array substrate in any one of a fringe field switching (FFS) type liquid crystal display panel, an advanced super dimension switch (ADS) type liquid crystal display panel, and a high advanced super dimension switch (HADS) type liquid crystal display panel.

Optionally, the common voltage line 5 includes: a first common voltage sub-line 51 located in each first dummy sub-region 31, extending along the second direction Y, and located between the active gate lines 9 and the corresponding gate driving circuit. A portion of the first common voltage sub-line 51 directly opposite to the end of each active gate line 9 in the first direction X is an avoiding portion 51a (or a bypassed portion 51a), and an orthographic projection of each second conductive connection structure 10 on the base substrate 1 does not overlap with an orthographic projection of the corresponding avoiding portion 51a on the base substrate 1. Referring to FIGS. 3A and 3B and FIGS. 4A to 4D, the second conductive connection structure 10 is essentially a winding line for bypassing a region where the corresponding avoiding portion 51a is located.

In some embodiments, the second conductive connection structures 10, the active data lines 7 and the dummy data lines 6 are disposed in the same layer.

In the embodiment of the present disclosure, the portion of the first common voltage sub-line 51 directly opposite to the end of each active gate line 9 in the first direction X specifically means: a portion of the first common voltage sub-line 51 which is covered by an orthographic projection of the end of the active gate line 9 in the first direction X on the first common voltage sub-line 51. A width of the end of the active gate line 9 in the second direction Y is equal to or substantially equal to a width of the avoiding portion of the first common voltage sub-line 51 directly opposite to the end in the second direction Y.

As can be seen from the drawings, the first common voltage sub-line 51 and the active gate line 9 are both made of bulk metals, where charges are easily accumulated in the manufacturing process. In the subsequent manufacturing process, there is a certain probability that the charges are discharged from the end of the active gate line 9 to the portion (the avoiding portion) of the first common voltage sub-line 51 directly opposite to the end, which easily damages a structure of a region where the avoiding portion 51a is located. For example, if a portion of the gate insulating layer GI located in the region where the avoiding portion 51a is located is broken down due to an electrostatic discharge occurring at an end of the active gate line 9, and the second conductive connection structure 10 just extends to the region where the avoiding portion is located, a short circuit between the second conductive connection structure 10 and the avoiding portion 51a is likely to occur, which causes the active gate line 9 connected to the second conductive connection structure 10 to be short-circuited to the common voltage line 5, and thus causes the active pixel unit connected to the active gate line 9 to have a poor display.

It should be noted that when the second dummy gate line 11 is disposed on the display substrate, a portion of the first common voltage sub-line 51 directly opposite to an end of the second dummy gate line 11 in the first direction X is further used as an avoiding portion 51a, and an orthographic projection of the conductive connection structure 12 for connecting the end of the second dummy gate line 11 and the corresponding gate driving circuit on the base substrate 1 may not overlap with an orthographic projection of the avoiding portion 51a on the base substrate 1.

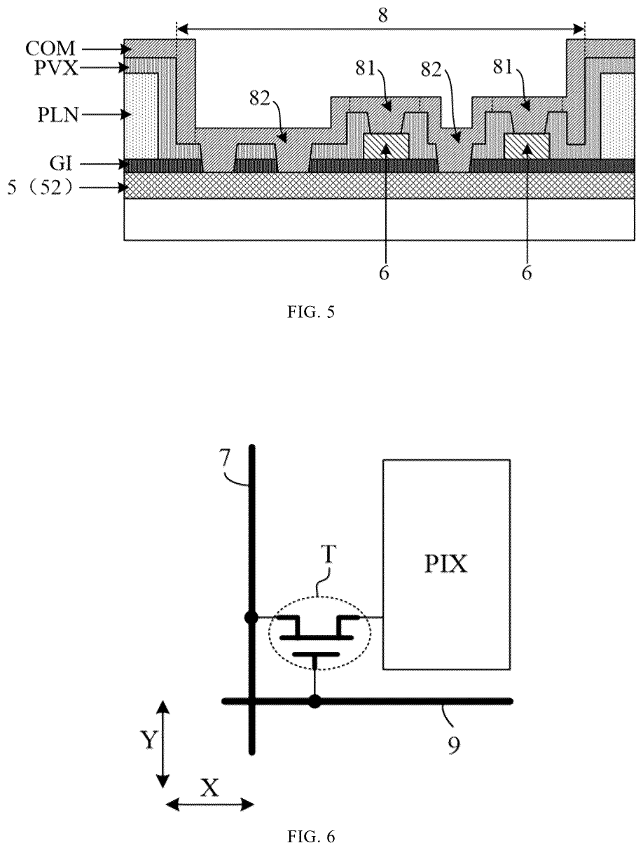

FIG. 8 is another schematic top view of a display substrate according to an embodiment of the present disclosure. As shown in FIG. 8, in some embodiments, the base substrate 1 further includes the peripheral region 4 surrounding the dummy region 3, and the peripheral region 4 includes: a bonding sub-region, first peripheral sub-regions 41 and first corner sub-regions 44. The bonding sub-region 42 is located on one side of the active display region 2 in the second direction Y, each first peripheral sub-region 41 is located on a side of the corresponding first dummy sub-region 31 away from the active display region 2, and each first corner sub-region 44 is located between the bonding sub-region 42 and the corresponding first peripheral sub-region 41.

A plurality of test terminals 71 (CT pads) are arranged in each first corner sub-region 44, a plurality of test lines 72 are arranged in each first peripheral sub-region 41, and one end of each test line 72 close to the bonding sub-region 42 extends into the first corner sub-region 44 and is connected to the corresponding test terminal 71. A plurality of first electrostatic discharge units 74 are arranged in each first corner sub-region, a portion of each test line 72 located in the first corner sub-region 44 is connected to the corresponding first electrostatic discharge unit 74 through a corresponding third conductive connection structure 73, and the test terminal 71 and the test line 72 connected to the test terminal share the first electrostatic discharge unit 74.

A plurality of connection terminals 81 are disposed in the bonding sub-region 42 and are configured to bond the source driving chip (not shown) and the flexible circuit board (not shown) in the bonding sub-region 42, and the source driving chip may be configured to provide a data voltage for display to the active data lines 7. In addition, a MUX circuit (not shown) may be disposed in the bonding sub-region 42 and between the active data lines 7 and the source driving chip, which is beneficial to reduce the number of output channels of the source driving chip.

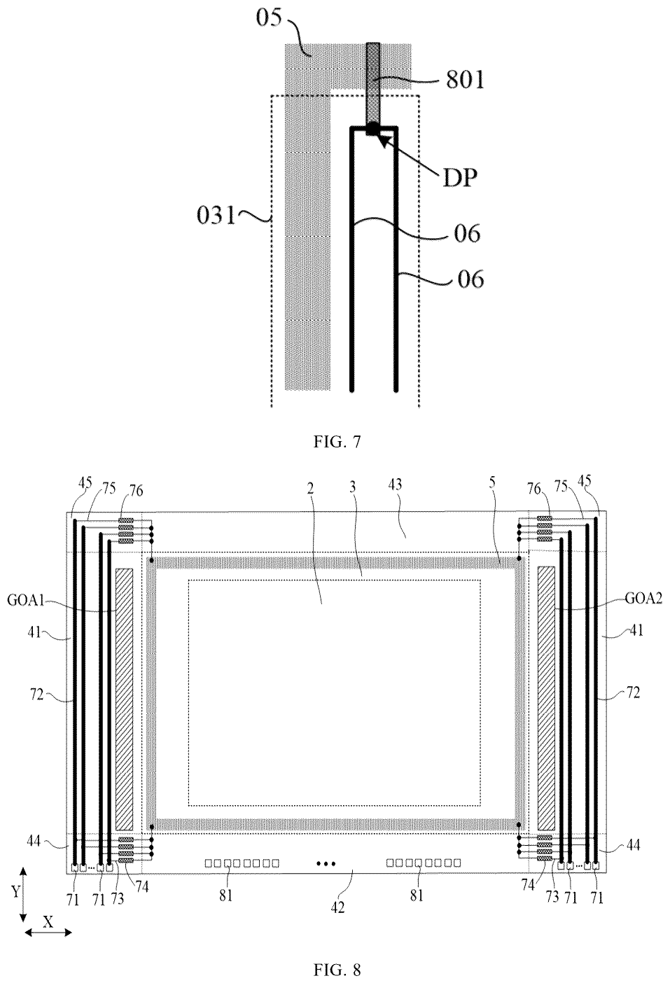

FIG. 9 is a schematic top view of a structure at a test terminal in a related art. As shown in FIG. 9, in order to enable an electrostatic discharge function of the test terminal 71 in the related art, an electrostatic discharge unit 80, such as an electrostatic discharge unit formed by transistors, is generally disposed between every two adjacent test terminals 71. However, as may be seen from FIG. 9, a distance between adjacent test terminals 71 is small, and the electrostatic discharge unit 80 is required to be formed in the small space, which has a high requirement for the alignment precision in the manufacturing process and a low production yield of the production line, and requires the electrostatic discharge unit 80 itself to be designed to have a small size (for example, the electrostatic discharge unit includes small-sized transistors). Therefore, the electrostatic discharge unit 80 is easily conducted, and the adjacent test terminals 71 are short-circuited to each other, and cannot be used for normal testing.

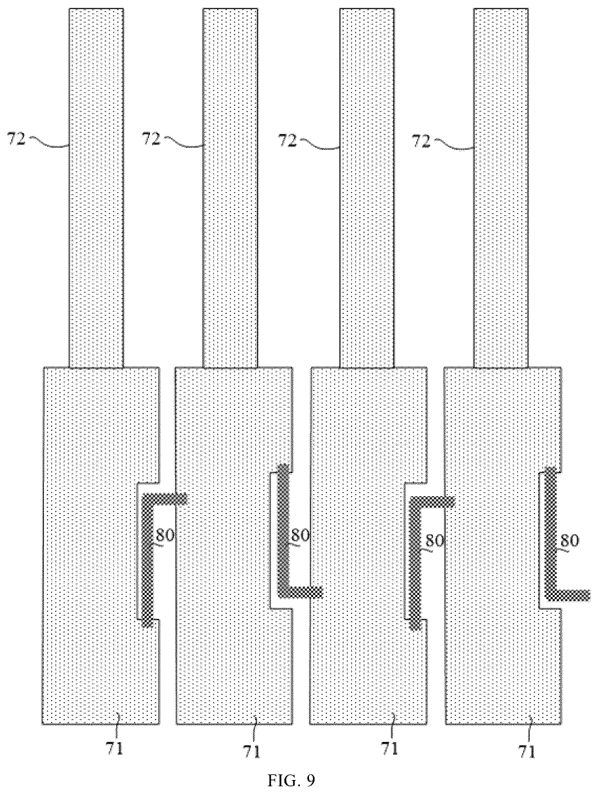

FIG. 10 is a schematic top view of a structure at a test terminal according to an embodiment of the present disclosure. As shown in FIG. 10, in order to effectively solve the above technical problem, in the embodiment of the present disclosure, the first electrostatic discharge unit 74 is provided for the portion of the test line 72 located in the first corner sub-region 44, so that the portion of the test line 72 located in the first corner sub-region 44 has a better electrostatic discharge capability. The portion of the testing line 72 located in the first corner sub-region 44 is connected to the corresponding testing terminal 71, so that the testing terminal 71 connected to the portion of the testing line 72 located in the first corner sub-region 44 have better electrostatic discharge capability has a better electrostatic discharge capability by providing the first electrostatic discharge unit 74. That is, the test terminal 71 and the test line 72 connected to each other may share the first electrostatic discharge unit 74. Therefore, it is not necessary to provide the electrostatic discharge unit between every two adjacent test terminals 71 connected to each other, so that the above technical problem in the related art as in FIG. 9 can be effectively solved or alleviated.

In some embodiments, the peripheral region 4 further includes: a bonding opposite sub-region 43 and second corner sub-regions 45, the bonding opposite sub-region 43 and the bonding sub-region 42 are located on two opposite sides of the active display region 2 in the second direction Y, respectively, and each second corner sub-region is located between the bonding opposite sub-region 43 and the corresponding first peripheral sub-region 41. A plurality of second electrostatic discharge units 76 are arranged in each second corner sub-region 45, one end of each test line 72 close to the bonding opposite sub-region 43 extends into the corresponding second corner sub-region 45, and a portion of each test line 72 located in the second corner sub-region 45 is connected to the corresponding second electrostatic discharge unit 76 through a corresponding fourth conductive connection structure 75. The test terminal 71 shares the second electrostatic discharge unit 76 with the test line 72 connected to the test terminal 71. By providing the second electrostatic discharge unit 76, the electrostatic discharge capability of the test line 72 and the test terminal 71 can be further improved.

In some embodiments, the test lines 72 and the common voltage line 5 are disposed in the same layer. The third conductive connection structures 73, the fourth conductive connection structures 75 and the dummy data lines 6 are disposed in the same layer.

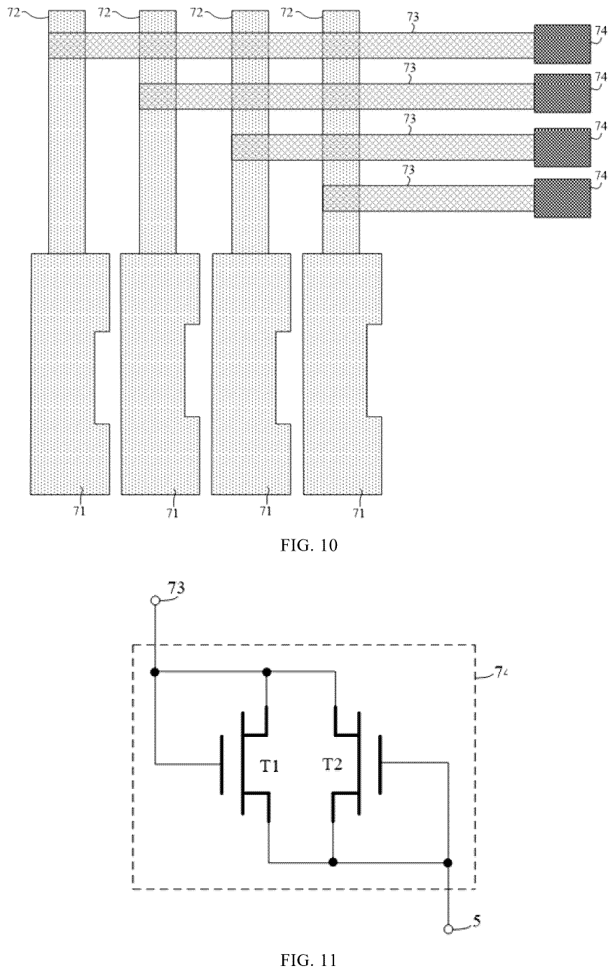

FIG. 11 is a schematic diagram of a circuit structure of a first electrostatic discharge unit according to an embodiment of the present disclosure. As shown in FIG. 11, in some embodiments, the first electrostatic discharge unit 74 includes: a first transistor Tl and a second transistor T2. A gate electrode of the first transistor Tl and a first electrode of the first transistor Tl are connected to the corresponding third conductive connection structure, and a second electrode of the first transistor Tl is connected to the common voltage line 5. A gate electrode of the second transistor T2 and a second electrode of the second transistor T2 are connected to the common voltage line 5, and a first electrode of the second transistor T2 is connected to the corresponding third conductive connection structure 73.

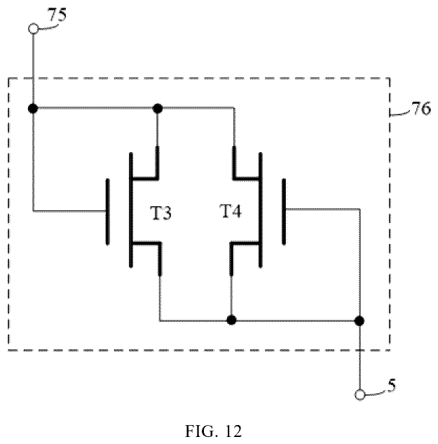

FIG. 12 is a schematic diagram of a circuit structure of a second electrostatic discharge unit according to an embodiment of the present disclosure. As shown in FIG. 12, in some embodiments, the second electrostatic discharge unit 76 includes: a third transistor T3 and a fourth transistor T4. A gate electrode of the third transistor T3 and a first electrode of the third transistor T3 are connected to the corresponding fourth conductive connection structure 75, and a second electrode of the third transistor T3 is connected to the common voltage line 5. A gate electrode of the fourth transistor T4 and a second electrode of the fourth transistor T4 are connected to the common voltage line 5, and a first electrode of the fourth transistor T4 is connected to the corresponding fourth conductive connection structure 75.

Alternatively, the first electrostatic discharge unit 74 and the second electrostatic discharge unit 76 in the embodiment of the present disclosure are not limited to the structure composed of the two transistors as shown in FIGS. 11 and 12, and it should be understood by one of ordinary skill in the art that any structure having an electrostatic discharge function may be used as the first electrostatic discharge unit 74 or the second electrostatic discharge unit 76 in the present disclosure.

Based on the same inventive concept, the embodiment of the present disclosure further provides a display panel, including: a display substrate and an opposite substrate opposite to the display substrate, and the display substrate may be the display substrate provided in the above embodiments.

Based on the same inventive concept, the embodiment of the present disclosure further provides a display apparatus, including a display panel, and the display panel is the display substrate provided in the above embodiments. The display apparatus may further include a driving module for driving the display panel to display.

Optionally, the driving module includes: a source driving chip connected to the active data lines, and configured to provide data voltages to the active data lines.

The display apparatus in the embodiments of the present disclosure may be specifically an electronic tag, a tablet computer, a notebook computer, a palm computer, a vehicle-mounted electronic device, a mobile internet device (MID), an augmented reality (AR)/virtual reality (VR) device, a robot, a wearable device, an ultra mobile personal computer (UMPC), a netbook, a personal digital assistant (PDA), a personal computer (PC), a television (TV), a mobile phone, an electronic photo frame, a navigator, a teller machine, a self-service machine, or other display products or components with a display function.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A display substrate, comprising:
a base substrate comprising an active display region and a dummy region surrounding the active display region, wherein the dummy region comprises at least one first dummy sub-region arranged in a first direction together with the active display region;
a plurality of active gate lines in the active display region and extending along the first direction, wherein at least one end of at least one active gate line each extends into a first dummy sub-region of the at least one first dummy sub-region on the same side as the end; and
at least one dummy data line within the at least one first dummy sub-region and extending along a second direction, wherein the first direction intersects with the second direction;
wherein an orthographic projection of an end of the at least one active gate line in the first dummy sub-region on the base substrate does not overlap with an orthographic projection of any dummy data line on the base substrate.

2. The display substrate of claim 1, wherein the dummy region comprises two first dummy sub-regions on two opposite sides of the active display region in the first direction, respectively; and
two ends of each of the at least one active gate line extend into the two first dummy sub-regions at the two opposite sides corresponding to the two ends, respectively.

3. The display substrate of claim 1, wherein the end of each of the at least one active gate line extending to the corresponding first dummy sub-region is on a side of one dummy data line, farthest from the active display region in the first dummy sub-region where the end is located, away from the active display region.

4. The display substrate of claim 1, wherein the at least one dummy data line within the first dummy sub-region comprises two or more dummy data lines; and
the end of each of the at least one active gate line extending to the corresponding first dummy sub-region is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region.

5. The display substrate of claim 1, wherein the dummy region comprises two first dummy sub-regions on two opposite sides of the active display region in the first direction, respectively, the base substrate further comprises a peripheral region surrounding the dummy region and comprising: two first peripheral sub-regions, each of which is on a side of a corresponding one of the two first dummy sub-regions away from the active display region, and the display substrate further comprises a first gate driving circuit and a second gate driving circuit in the two first peripheral sub-regions, respectively;
the plurality of active gate lines in the active display region comprise: a plurality of first gate lines and a plurality of second gate lines alternately arranged along the second direction;
an end of each first gate line close to the first gate driving circuit is on a side of one dummy data line, farthest from the active display region in the first dummy sub-region where the end is located, away from the active display region, and the first gate line is connected to a corresponding driving signal output terminal in the first gate driving circuit; and
an end of each second gate line close to the second gate driving circuit is on a side of one dummy data line, farthest from the active display region in the first dummy sub-region where the end is located, away from the active display region, and the second gate line is connected to a corresponding driving signal output terminal in the second gate driving circuit.

6. The display substrate of claim 5, wherein the at least one dummy data line within the first dummy sub-region comprises two or more dummy data lines;
an end of each first gate line close to the second gate driving circuit is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region; and
an end of each second gate line close to the first gate driving circuit is between two dummy data lines farthest from the active display region in the first dummy sub-region where the end is located, and a portion, opposite to the end in the first direction, of the one dummy data line farthest from the active display region in the first dummy sub-region where the end is located, protrudes away from the active display region.

7. The display substrate of claim 1, wherein the dummy region comprises two first dummy sub-regions on two opposite sides of the active display region in the first direction, respectively, the base substrate further comprises a peripheral region surrounding the dummy region and comprising: two first peripheral sub-regions, each of which is on a side of a corresponding one of the two first dummy sub-regions away from the active display region, and the display substrate further comprises a first gate driving circuit and a second gate driving circuit in the two first peripheral sub-regions, respectively;
an end of each active gate line close to the first gate driving circuit is on a side of one dummy data line, farthest from the active display region in the first dummy sub-region where the end is located, away from the active display region, and the active gate line is connected to a corresponding driving signal output terminal in the first gate driving circuit; and
an end of each active gate line close to the second gate driving circuit is on a side of one dummy data line, farthest from the active display region in the first dummy sub-region where the end is located, away from the active display region, and the active gate line is connected to a corresponding driving signal output terminal in the second gate driving circuit.

8. The display substrate of claim 1, wherein the display substrate further comprises: a common voltage line in the dummy region; and
the plurality of active gate lines and the common voltage line are arranged in a same layer; and
wherein a distance in the first direction between the end of each active gate line extending to the corresponding first dummy sub-region and any one dummy data line in the first dummy sub-region where the end is located is greater than or equal to 7 μm and less than or equal to 20 μm.

9. (canceled)

10. The display substrate of claim 1, wherein the display substrate further comprises:
a common voltage line in the dummy region; and
a plurality of active data lines in the active display region, extending along the second direction, and insulated from the common voltage line; and
the at least one dummy data line within the first dummy sub-region comprises two or more dummy data lines connected to the common voltage line, and at least two dummy data lines are not in contact with each other,
wherein the display substrate further comprises:
first conductive connection structures on a side of the two or more dummy data lines away from the base substrate;
wherein the two or more dummy data lines are connected to the common voltage line through corresponding first conductive connection structures, respectively, the first conductive connection structures each comprise a first portion and a second portion connected to each other, the first portion is connected to the corresponding dummy data line, and the second portion is connected to the common voltage line.

11. (canceled)

12. The display substrate of claim 10, wherein the dummy region further comprises: two second dummy sub-regions on two opposite sides of the active display region in the second direction;
the common voltage line comprises: two second common voltage sub-lines in the two second dummy sub-regions, respectively, and extending along the first direction; and
two ends of each dummy data line are connected to the two second common voltage sub-lines through the corresponding first conductive connection structures, respectively; and
wherein orthographic projections of the two ends of each dummy data line on the base substrate overlap with orthographic projections of the two second common voltage sub-lines on the base substrate, respectively.

13. (canceled)

14. The display substrate of claim 12, wherein the two ends of each dummy data line are a first end and a second end, respectively;
first ends of at least two dummy data lines in a same first dummy sub-region are connected to different portions of a same first conductive connection structure of the first conductive connection structures; and
second ends of the at least two dummy data lines in a same first dummy sub-region are connected to different portions of a same first conductive connection structure of the first conductive connection structures.

15. The display substrate of claim 1, further comprising:
a gate insulating layer on a side of the common voltage line away from the base substrate, wherein the at least one dummy data line is on a side of the gate insulating layer away from the base substrate;
a planarization layer on a side of the at least one dummy data line away from the base substrate;
a pixel electrode layer on a side of the planarization layer away from the base substrate, and comprising a plurality of pixel electrodes; and
a passivation layer on a side of the pixel electrode layer away from the base substrate;
wherein the first conductive connection structures are on a side of the passivation layer away from the base substrate, the first portion is connected to the corresponding dummy data line through a via in the passivation layer exposing a surface of the corresponding dummy data line, and the second portion is connected to the common voltage line through a via in the passivation layer, the planarization layer, and the gate insulating layer exposing a surface of the common voltage line; and
the display substrate further comprises a common electrode on a side of the plurality of active data lines away from the base substrate; and
a portion of the common electrode serves as the first conductive connection structure.

16. (canceled)

17. The display substrate of claim 1, wherein the base substrate further comprises a peripheral region surrounding the dummy region, and comprising: a first peripheral sub-region on a side of the first dummy sub-region away from the active display region, wherein a gate driving circuit is arranged in the first peripheral sub-region, and at least one end of each active gate line is connected to at least one corresponding driving signal output terminal in the gate driving circuit through at least one corresponding second conductive connection structure, respectively;
the common voltage line comprises: a first common voltage sub-line in the first dummy sub-region, extending along the second direction and between the plurality of active gate lines and the gate driving circuit; and
a portion of the first common voltage sub-line directly opposite to the end of each active gate line in the first direction is an avoiding portion, and an orthographic projection of each second conductive connection structure on the base substrate does not overlap with an orthographic projection of the corresponding avoiding portion on the base substrate; and
wherein the common voltage line is in the same layer as the plurality of active gate lines; and
the second conductive connection structure is in the same layer as the plurality of active data lines and the at least one dummy data line.

18. (canceled)

19. The display substrate of claim 1, wherein the base substrate further comprises a peripheral region surrounding the dummy region, and comprising: a bonding sub-region, first peripheral sub-regions and first corner sub-regions, the bonding sub-region is on one side of the active display region in the second direction, each first peripheral sub-region is on a side of the corresponding first dummy sub-region away from the active display region, and each first corner sub-region is between the bonding sub-region and the corresponding first peripheral sub-region;
the display substrate further comprises a plurality of test terminals in each first corner sub-region and a plurality of test lines in each first peripheral sub-region, and one end of each test line close to the bonding sub-region extends into the first corner sub-region and is connected to the corresponding test terminal;
the display substrate further comprises a plurality of first electrostatic discharge units in each first corner sub-region, and a portion of each test line in the first corner sub-region is connected to the corresponding first electrostatic discharge unit through a corresponding third conductive connection structure, and
each test terminal and the test line connected to the test terminal share a same first electrostatic discharge unit.

20. The display substrate of claim 19, wherein each first electrostatic discharge unit comprises: a first transistor and a second transistor;
a gate electrode of the first transistor and a first electrode of the first transistor are connected to the corresponding third conductive connection structure, and a second electrode of the first transistor is connected to the common voltage line; and
a gate electrode of the second transistor and a second electrode of the second transistor are connected to the common voltage line, and a first electrode of the second transistor is connected to the corresponding third conductive connection structure; and
wherein the peripheral region further comprises: a bonding opposite sub-region and second corner sub-regions, wherein the bonding opposite sub-region and the bonding sub-region are on two opposite sides of the active display region in the second direction, respectively, and each second corner sub-region is between the bonding opposite sub-region and the corresponding first peripheral sub-region;
the display substrate further comprises a plurality of second electrostatic discharge units in each second corner sub-region, one end of each test line close to the bonding opposite sub-region extends into the corresponding second corner sub-region, and a portion of each test line in the second corner sub-region is connected to the corresponding second electrostatic discharge unit through a corresponding fourth conductive connection structure; and
each test terminal and the test line connected to the test terminal share a same second electrostatic discharge unit.

21. (canceled)

22. The display substrate of claim 20, wherein each second electrostatic discharge unit comprises: a third transistor and a fourth transistor;
a gate electrode of the third transistor and a first electrode of the third transistor are connected to the corresponding fourth conductive connection structure, and a second electrode of the third transistor is connected to the common voltage line; and
a gate electrode of the fourth transistor and a second electrode of the fourth transistor are connected to the common voltage line, and a first electrode of the fourth transistor is connected to the corresponding fourth conductive connection structure; and
wherein the plurality of test lines are in the same layer as the common voltage line; and
the third conductive connection structure, the fourth conductive connection structure and the at least one dummy data line are arranged in a same layer.

23. (canceled)

24. A display panel, comprising: the display substrate of claim 1 and an opposite substrate opposite to the display substrate.

25. A display apparatus, comprising: the display panel of claim 24 and a source driving chip;
wherein the source driving chip is connected to the plurality of active data lines and configured to provide a data voltage for each of the plurality of active data lines.

26. The display substrate of claim 1, wherein the dummy region comprises two first dummy sub-regions on two opposite sides of the active display region in the first direction, respectively, the base substrate further comprises a peripheral region surrounding the dummy region and comprising: two first peripheral sub-regions, each of which is on a side of a corresponding one of the two first dummy sub-regions away from the active display region, and the display substrate further comprises a first gate driving circuit and a second gate driving circuit in the two first peripheral sub-regions, respectively;
the plurality of active gate lines in the active display region comprise: a plurality of first gate lines and a plurality of second gate lines alternately arranged along the second direction;
one end of each active gate line close to the first gate driving circuit is on a side of one dummy data line, farthest from the active display region in the first dummy sub-region where the one end is located, away from the active display region, and the active gate line is connected to a corresponding driving signal output terminal in the first gate driving circuit, and the other end of the active gate line close to the second gate driving circuit is between two dummy data lines farthest from the active display region in the first dummy sub-region where the other end is located, and a portion, opposite to the other end in the first direction, of the one dummy data line farthest from the active display region in the first dummy sub-region where the other end is located, protrudes away from the active display region; and
one end of each active gate line close to the second gate driving circuit is on a side of one dummy data line, farthest from the active display region in the first dummy sub-region where the one end is located, away from the active display region, and the active gate line is connected to a corresponding driving signal output terminal in the second gate driving circuit, and the other end of each second gate line close to the first gate driving circuit is between two dummy data lines farthest from the active display region in the first dummy sub-region where the other end is located, and a portion, opposite to the other end in the first direction, of the one dummy data line farthest from the active display region in the first dummy sub-region where the other end is located, protrudes away from the active display region.

27. The display substrate of claim 26, wherein the portion comprises a first segment, a second segment, a second segment and a third segment connected in sequence;
the first segment and the third segment extend along the first direction; and the third segment extends along the third direction; and
the other end of the active gate line is opposite to the second segment connected between the first segment and the third segment.
